(19) United States
(12) Patent Application Publication
(10) Pub. No.: US 2008/0121946 A1
(43) Pub. Date: May 29, 2008

(54) METHOD OF FORMING SENSOR FOR DETECTING GASES AND BIOCHEMICAL MATERIALS, INTEGRATED CIRCUIT HAVING THE SENSOR, AND METHOD OF MANUFACTURING THE INTEGRATED CIRCUIT

(76) Inventors: Doo Hyeb YOUN, Daejeon-city (KR); Sunglyul MAENG, Daejeon-city (KR); Sang Hyeob KIM, Daejeon-city (KR); Jonghyurk PARK, Daegu-city (KR); Kwang Yong KANG, Daejeon-city (KR); Sang Hoon LEE, Daejeon-city (KR); Chull Won JU, Daejeon-city (KR)

Correspondence Address: LADAS & PARRY LLP, 224 SOUTH MICHIGAN AVENUE, SUITE 1600, CHICAGO, IL, 60604, US

(21) Appl. No.: 11/736,658

(22) Filed: Apr. 18, 2007

(30) Foreign Application Priority Data
Aug. 31, 2006 (KR) 10-2006-0083570

(51) Int. Cl. H01L 29/78; H01L 21/00

(52) U.S. Cl. 257/253; 438/49; 257/E29.255; 257/E21.001

(57) ABSTRACT

A method of forming a sensor for detecting gases and biochemical materials that can be fabricated at a temperature in a range from room temperature to 400° C., a metal oxide semiconductor field effect transistor (MOSFET)-based integrated circuit including the sensor, and a method of manufacturing the integrated circuit are provided. The integrated circuit includes a semiconductor substrate. The sensor for detecting gases and biochemical materials includes a pair of electrodes formed on a first region of the semiconductor substrate, and a metal oxide nano structure layer formed on surfaces of the pair electrodes. A heater is formed to perform thermal treatment to re-use the material detected in the metal oxide nano structure layer. Also, a signal processor is formed by a MOSFET to process a predetermined signal obtained from a quantity change of a current flowing through the pair of electrodes of the sensor. To form the sensor, the metal oxide nano structure layer is formed on surfaces of the pair of electrodes at a temperature in a range from room temperature to 400° C.

### CROSS-REFERENCE TO RELATED PATENT APPLICATION

This application claims the benefit of Korean Patent Application No. 10-2006-0083570, filed on Aug. 31, 2006, in the Korean Intellectual Property Office, the disclosure of which is incorporated herein in its entirety by reference.

### BACKGROUND OF THE INVENTION

1. Field of the Invention

The present invention relates to a method of forming a sensor, an integrated circuit having the sensor, and a method of manufacturing the integrated circuit. More particularly, the present invention relates to a method of forming a sensor for detecting gases and biochemical materials, an integrated circuit including a metal oxide semiconductor field effect transistor (MOSFET) having the sensor, and a method of manufacturing the integrated circuit.

2. Description of the Related Art

As environmental pollution and global warming have become more severe, the development of gas sensors for detecting the existence or quantity of a specific gas has been accelerated. Also, studies for developing sensors for detecting gases or biochemical materials are actively carried out in biotechnology and clinical health areas. Such sensors for detecting gases or biochemical materials have been remarkably developed in electronic engineering and information telecommunication areas. In order to minimize and integrate these sensors, it is required to develop a sensor using a fine electrode and an electrochemical measuring system.

Most of the sensors for detecting gases and biochemical materials suggested until now use a change of an electrical reaction to detect gases or biochemical materials. An electrical property of a solid is affected by a material that has to be detected, and a specific gas or biochemical material is detected from such a change. Currently-known solid-state sensors can be classified into three types: semiconductor sensors changing the electron conductivity of a semiconductor when a biochemical material to be detected is sucked or absorbed; solid-state electrolysis material sensors changing an ion current flowing through a solid when a biochemical material is detected; and magnetic field transistor biochemical material sensors (chemical thin film transistors) in which detection of a biochemical material affects a potential of a gate of a magnetic field effect transistor.

The biochemical material sensor for detecting a specific biochemical material may be classified into a reduction type biochemical material sensor for sensing CO and a hydrocarbon based biochemical material, a sensor for sensing C₂H₅OH, a sensor for sensing freshness of fish, and a sensor for detecting a degree of meat corruption.

Currently, sensors must be miniaturized so as to be used for managing air-conditioning systems within buildings, offices and factories, managing manufacturing of food, beverages, and alcohol, and detecting a specific biochemical material, toxic gas, or stink. Moreover, a miniature sensor should necessarily be integrated in a single substrate together with unit elements having various functions.

However, currently-suggested sensors for detecting gases or biochemical materials are of a ceramic type or a thick film type, which, thus, make a miniaturization process difficult. Furthermore, when manufacturing the currently-suggested sensors for detecting gases or biochemical materials, a high temperature condition of about 900° C. or greater is required to make a metal oxide film grow. Therefore, when a sensor is formed together with unit elements having various composite functions, MOSFET-based unit elements are degraded. Accordingly, the integration of the sensors and the unit elements altogether is difficult.

### SUMMARY OF THE INVENTION

The present invention provides an integrated circuit including a miniature sensor for detecting gases and biochemical materials and unit elements having various composite functions.

The present invention also provides a method of manufacturing an integrated circuit including a miniature sensor for detecting gases and biochemical materials and unit elements having various composite functions by low temperature processing without degrading or lowering characteristics of MOSFET-based unit elements.

The present invention also provides a method of manufacturing a miniature sensor for detecting gases and biochemical materials by low temperature processing that allows for integration together with unit elements having various composite functions.

According to an aspect of the present invention, there is provided an integrated circuit including a semiconductor substrate. A sensor for detecting gases and biochemical materials includes a pair of electrodes formed on a first region of the semiconductor substrate, and a metal oxide nano structure layer formed on surfaces of the pair electrodes. A heater is formed on a second region adjacent to the sensor on the semiconductor substrate. Also, a signal processor is formed by a metal oxide semiconductor field effect transistor (MOSFET) formed in a third region of the semiconductor substrate to process a predetermined signal obtained from a quantity change of a current flowing through the pair of electrodes of the sensor.

According to another aspect of the present invention, there is provided a method of manufacturing an integrated circuit, including forming a plurality of MOSFET devices on a substrate; forming a sensor for detecting gases and biochemical materials on the plurality of MOSFET devices, wherein the forming of the sensor includes forming a passivation film that covers the plurality of MOSFET devices on the substrate; forming at least one pair of electrodes on the passivation film, and forming a metal oxide nano structure layer on the surfaces of the pair of electrodes at a temperature between room temperature and 400° C.

The forming of the plurality of MOSFET devices on the substrate may include forming a MOSFET device that constitutes a signal processor for processing a predetermined signal obtained by a quantity change of a current flowing through the pair of electrodes of the sensor.

Furthermore, the forming of the plurality of MOSFET devices includes forming a MOSFET device that constitutes a heater for supplying heat to the sensor.

According to another aspect of the present invention, there is provided a method of forming a sensor for detecting gases and biochemical materials, including forming electrodes on a substrate; and forming a metal oxide nano structure layer on surfaces of the electrodes at a temperature between room temperature and 400° C.

The metal oxide nano structure layer may be formed by radio-frequency (RF) sputtering.

The metal oxide nano structure layer may be composed of zinc oxide, indium oxide, tin oxide, tungsten oxide or vanadium oxide.

The forming of the metal oxide nano structure layer is performed within a chamber by supplying ambient gas including O₂ and Ar into the chamber.

According to the present invention, a sensor for detecting gases and biochemical materials that can be formed without performing an additional thermal treatment at high temperature is embodied on a substrate where MOSFET unit devices are formed. Therefore, characteristics degradation of an integrated circuit caused by heating the unit devices when forming the sensor can be prevented, and fine unit elements having various composite functions can be integrated on a single substrate together with the sensor.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram illustrating an integrated circuit according to an embodiment of the present invention;

FIG. 2A is a plan view partially illustrating an exemplary construction of a sensor for detecting gases and biochemical materials according to an embodiment of the present invention;

FIG. 2B is an enlarged sectional view taken along line IIb-IIb′ of FIG. 2A;

FIG. 3 is a sectional view illustrating an integrated circuit according to an embodiment of the present invention;

FIG. 4 shows SEM images displaying growths in terms of flow rate ratios of 0₂/Ar of zinc oxide nano structures included in the sensor for detecting gases and biochemical materials according to an embodiment of the present invention;

FIG. 5 illustrates results of analyzing X-ray diffraction peaks with respect to the results of FIG. 4;

FIG. 6 illustrates an Auger Electron Spectroscopy (AES) pattern with respect to the results of FIG. 4;

FIG. 7 shows SEM images displaying growths in terms of a growth time of the zinc oxide nano structures included in the sensor for detecting gases and biochemical materials according to another embodiment of the present invention;

FIG. 8 illustrates results of analyzing X-ray diffraction peaks with respect to the results of FIG. 7;

FIG. 9 illustrates an AES pattern with respect to the results of FIG. 7; and

FIG. 10 shows SEM images displaying results of making zinc oxide grow on two different electrodes under the same conditions.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. Like reference numerals in the drawings denote like elements, and thus their description will not be repeated.

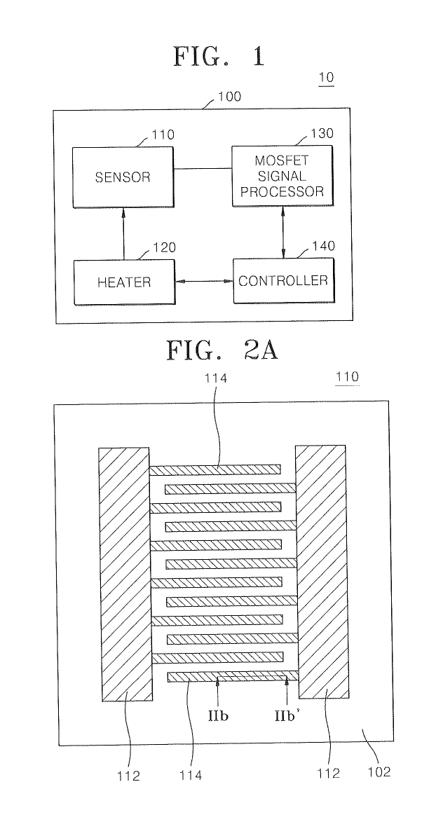

FIG. 1 is a block diagram illustrating an integrated circuit according to an embodiment of the present invention.

Referring to FIG. 1, an integrated circuit 10 includes a substrate 100 forming a single chip, and a sensor 110 for detecting gases and biochemical materials formed in a first region of the substrate 100. The substrate 100 may be, e.g., a silicon substrate or a silicon on insulator (SOI) substrate.

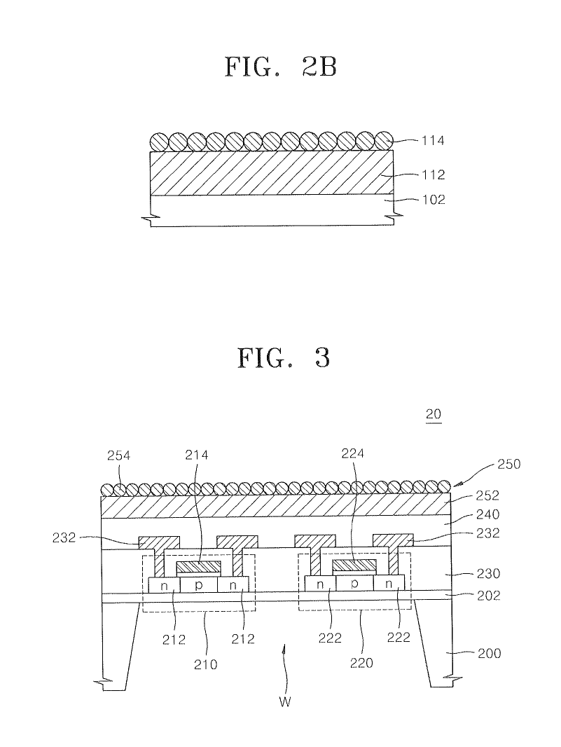

FIG. 2A is a plan view partially illustrating an exemplary construction of the sensor 110 for detecting gases and biochemical materials, according to an embodiment of the present invention. FIG. 2B is an enlarged sectional view taken along line IIb-IIb′ of FIG. 2A.

Referring to FIGS. 2A and 2B, the sensor 110 includes a pair of electrodes 112 formed on a predetermined film, i.e. a passivation film 102, on the substrate 100, and a metal oxide nano structure layer 114 formed on surfaces of the pair of electrodes 112. In this specification, the term “nano” denotes a size ranging from several tens to several hundreds of nm.

The metal oxide nano structure layer 114 may be formed on a surface of a portion of the electrodes 112, i.e., a partial region corresponding to a sensing region of the electrodes 112. The pair of electrodes 112 are shaped as a comb in FIG. 2A, but the present invention is not limited thereto. The pair of electrodes 112 may be formed in various forms in accordance with intended usage and design of the sensor.

The pair of electrodes 112 may be composed of a polycrystalline conductive material having an ohmic contact with a material constituting the metal oxide nano structure layer 114. For example, the pair of electrodes 112 may be composed of Au, Cu, Ti, Ni, or a combination of these materials. Moreover, the pair of electrodes 112 may have a stacked structure of Ni and Au, a stacked structure of Au and Cu, or a stacked structure of Ti and Cu.

The metal oxide nano structure layer 114 may be composed of zinc oxide (e.g., ZnO), indium oxide (e.g., In₂O₃), tin oxide (e.g., SnO₂), tungsten oxide (e.g., W₂O₃), or vanadium oxide (e.g., VO).

The metal oxide nano structure layer 114 may be formed by doping a p-type impurity or an n-type impurity as required. For example, when a p-type impurity is desired in forming the metal oxide nano structure layer 114 composed of ZnO, SnO₂, InₓO_{y} (where, x is an integer in the range of 1 to 3, and y is an integer in the range of 2 to 6), WO₃ and VₓO_{y} (where x is an integer in the range of 1 to 3, and y is an integer in the range of 2 to 6), a p-type impurity such as N, Cu, and Li is used to obtain the metal oxide nano structure layer 114 doped with the p-type impurity. Otherwise, when an n-type impurity is desired in forming the metal oxide nano structure layer 114 composed of the above-mentioned materials, an n-type impurity such as B, Al, Ga, In, and F is used to obtain the metal oxide nano structure layer 114 doped with the n-type impurity.

Referring again to FIG. 1, a heater 120 is formed in a second region close to a region having the sensor 110 on the substrate 100. The heater 120 is separated from the sensor 110 by interposing the passivation film (not shown) between them. The heater 120 supplies heat to the sensor 110. The heat generated from the heater 120 is transmitted to the sensor 110, thereby removing gases or biochemical materials sucked or absorbed in the sensor 110, thereby clearing the sensor 110 to an initial mode.

Furthermore, the heater 120 may be formed under the sensor 110 on the substrate 100. The heater 120 may be formed by an n-channel or p-channel MOSFET. Otherwise, the heater 120 may be formed by a stripe-type metal pattern. For example, the heater 120 may be composed of a high melting point metal such as Pt, Mo, and W. In this case, long-term reliability can be secured even when the heater 120 is continuously operated at high temperature.

Also, a signal processor 130 is formed on the substrate 100. The signal processor 130 is formed by MOSFET devices formed in a third region underlying the sensor 110 on the substrate 100 to process a predetermined signal obtained by a quantity change of current flowing through the pair of electrodes 112 that form the sensor 110. The signal processor 130 may be located on a portion separated from the sensor 110. As necessary, the signal processor 130 may be formed by a PMOS transistor, an NMOS transistor, a CMOS transistor, or respective arrays of these transistors. The sensor 110 and the signal processor 130 are separated from each other by interposing the passivation film (not shown) on the substrate 100. The signal processed in the signal processor 130 is transferred to a controller 140. The controller 140 amplifies the signal from the signal processor 130 to discriminate the gas or biochemical material to be detected. That is, the controller 140 discriminates and classifies a condition, i.e., kinds and amount, of the gas or the biochemical material to be detected. Also, in order to reset the sensor 110 to an initial mode by the heat generated from the heater 120 for a constant period, the controller 140 supplies a predetermined voltage to the heater 120, thereby the heater 120 generating heat.

FIG. 3 is a sectional view illustrating an integrated circuit according to an embodiment of the present invention.

An integrated circuit 20 with the structure as illustrated in FIG. 3 can be embodied on a silicon on insulator (SOI) substrate. In order to embody the integrated circuit 20, a heater 210 consisting of a MOS transistor is formed on an insulating film 202, e.g., a buried oxide film (BOX) or a silicon oxide film, on a silicon substrate 200 using a method of fabricating a conventional transistor. In FIG. 3, the heater 210 includes a source/drain 212 and a gate 214. The gate 214 may be composed of, e.g., polysilicon. Although the heater 210 is formed by an NMOS transistor in FIG. 3, the present invention is not limited thereto. The heater 210 may be formed by a PMOS transistor as required. Alternatively, the heater 210 may be composed of Pt or polysilicon. An electrode pad 232 consisting of a metal is connected to the source/drain 212 of the heater 210. A temperature sensor (not shown) consisting of a diode may be formed near the heater 210.

Also, a signal processor 220 consisting of a MOS transistor is formed on the silicon substrate 200. The signal processor 220 may include source/drain 222 and a gate 224. The gate 224 may be composed of, e.g., polysilicon. The signal processor 220 is constituted by an NMOS transistor in FIG. 3, but the present invention is not limited thereto. The signal processor 220 may consist of an NMOS transistor, a PMOS transistor, a CMOS transistor or respective arrays of these transistors. The signal processor 220 is adjacent to the heater 210 in FIG. 3, but the present invention is not limited thereto. That is, the signal processor 220 may be formed on a region spaced apart from the heater 210 on the silicon substrate 200.

The heater 210 and the signal processor 220 may be simultaneously formed by transistor forming processing, but either one of them may be formed first.

The heater 210, the temperature sensor (not shown) and the signal processor 220 are covered with an insulating film 230. The insulating film 230 may be, e.g., a silicon oxide film, a silicon nitride film or a combination of these films. The insulating film 230 is patterned by photolithography and wet etching in order to form contact holes that expose the source/drain 212 of the heater 210 and the source/drain 222 of the signal processor 220. Then, the contact holes are filled with a conductive material, e.g., a metal, to form the electrode pad 232.

The electrode pad 232 on the insulating film 230 is covered with a passivation film 240. The passivation film 240 may be, e.g., a silicon oxide film, a silicon nitride film, and a combination of these films. Thereafter, photolithography and wet etching are used to partially remove the silicon substrate 200 from a backside of the silicon substrate 200, thereby forming a window W.

A sensor 250 for detecting gases and biochemical materials is formed near the heater 210 on the passivation film 240, and more specifically, on the heater 210. As described with reference to FIGS. 2A and 2B, the sensor 250 includes an electrode 252 and a metal oxide nano structure layer 254 formed on a surface of the electrode 252.

In order to form the sensor 250, the electrode 252 having a predetermined pattern shape is formed on the passivation film 240. For this, after forming a metal film on the passivation film 240, photolithography, wet etching, or lift-off is used to pattern the metal film. The electrode 252 may have, e.g., an interdigitated (IDT) structure.

In the sensor for detecting gases and the biochemical materials according to the present invention, a sensing layer, i.e. the metal oxide nano structure layer, is heated at a specific temperature, e.g., about 100˜500° C., by an internal heater within the integrated circuit, so that the metal oxide nano structure layer sensitively reacts to a specific gas or biochemical material. Therefore, a power dissipation of the heater must be decreased. Accordingly, not only a material constituting the heater itself is highly efficient as a heat emitting body, but also a loss of the heat emitted from the heater to outside, i.e., portions except for the heater within the integrated circuit or the sensing layer adjacent to the heater, should be small. In order to prevent such a heat loss, the sensor structure for detecting gases and the biochemical materials has an integrated form obtained by sequentially stacking the heater 210, the temperature sensor (not shown), the passivation film 240 and the sensor 250 on the silicon substrate 200 where the window W is located as illustrated in FIG. 3.

In the sensors 110 and 250 for detecting gases and the biochemical materials respectively included in the integrated circuits 10 and 20 illustrated in FIGS. 1 through 3, the gases and biochemical materials detectable by the metal oxide nano structure layers 114 and 254 may include noxious materials such as CO, NO₂, SO₂, NH₃, H₂, H₂SO₄ and dioxin; sorts of alcohol such as C₂H₅OH; and biochemical materials such as DNA and protein. Additionally, the sensors 110 and 250 according to the present invention may be used for detecting freshness of fish and a degree of meat corruption.

In connection with the integrated circuit 20 illustrated in FIG. 3, radio frequency (RF) sputtering may be used for forming the metal oxide nano structure layer 254 on the electrode 252.

A method of forming the metal oxide nano structure layer 254 constituting the sensor 250 will be described by specific examples.

### EXAMPLE 1

In order to make a metal oxide nano structure layer grow using sputtering facility, an electrode formed of a polycrystalline metal film having a thickness of about 1000 nm was formed on an upper surface of a silicon substrate in a plane orientation (100). Thereafter, the silicon substrate formed with the electrode was loaded in a reaction chamber having a ZnO target, and ZnO was grown by using RF sputtering. A pressure within the reaction chamber was controlled to roughly 3.8×10⁻³ Pa or less, before growing the ZnO nano structure, i.e., before loading the silicon substrate within the reaction chamber. When the ZnO nano structure was being grown within the reaction chamber, a pressure of about 2.3 Pa was maintained within the reaction chamber and an RF power of about 150 watt is applied. While the ZnO nano structure was being grown within the reaction chamber, a temperature within the reaction chamber was maintained at room temperature.

### EXAMPLE 2

In order to observe the change of the nano structure form resulting from a quantity of oxygen in an ambient environment within the reaction chamber when making the metal oxide nano structure layer grow according to the method of the Example 1, ZnO nano structure was grown under a condition that O₂ and Ar have a flow rate ratio (O₂/Ar) of 0, 0.2 and 0.4, respectively.

For this operation, after a Ti thin film was formed on a p-type (100) silicon substrate, a Cu film was formed thereon for about 5 minutes by electro-plating. Thereafter, ZnO was grown on a surface of the Cu film for 15 minutes within the sputtering reaction chamber maintaining the temperature and pressure of the ambient environment as described in Example 1.

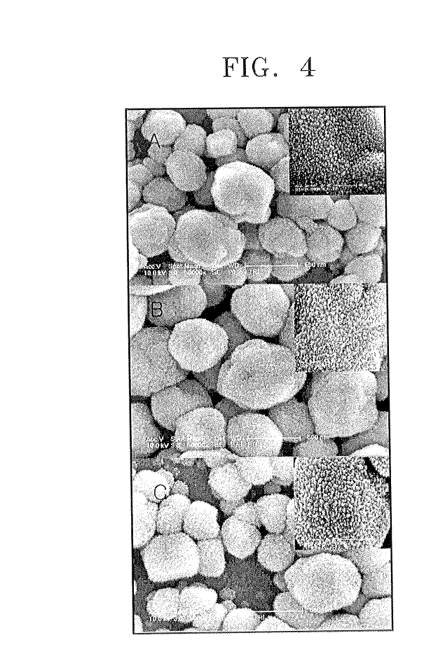

FIG. 4 shows SEM images displaying results of growing the ZnO nano structure each obtained according to a flow rate ratio of O₂/Ar as a result of Example 2.

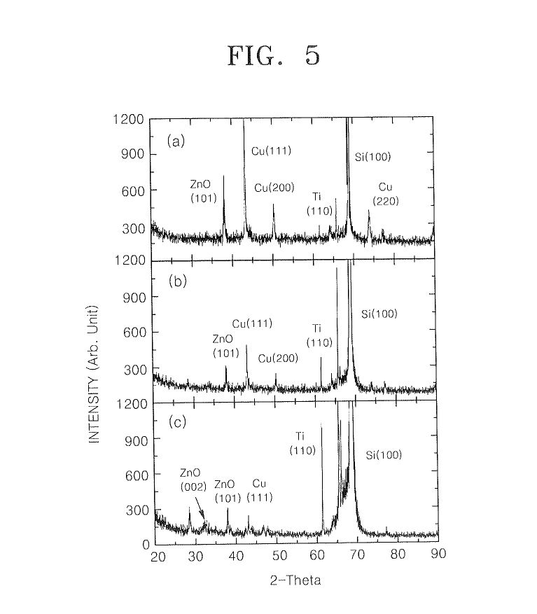

FIG. 5 illustrates results of analyzing X-ray diffraction peaks with respect to the results of FIG. 4.

In FIGS. 4 and 5, A and (a) were obtained when the flow rate ratio of O₂/Ar is 0, i.e., when O₂ was not supplied into the reaction chamber. B and (b) were obtained when the flow rate ratio is 0.2, i.e., when O₂ and Ar were respectively supplied in the flow rate of 6 sccm and 30 sccm into the reaction chamber. Also, C and (c) were obtained when the flow rate ratio was 0.4, i.e., O₂ and Ar were respectively supplied in the flow rate of 12 sccm and 30 sccm.

In FIG. 4, when the O₂/Ar flow rate ratio was 0.2 and 0.4, a ZnO nano structure with a diameter of about 30˜70 nm was formed on a surface of a Cu/Ti electrode.

After analyzing an X-ray diffraction peak pattern of FIG. 5, two peaks at 33.8° and 38.0° each corresponding to the plane orientation (002) and (101) of ZnO that is a hexagonal lattice in (c) of FIG. 5 were confirmed (also confirmed by data from JCPDS International Center).

From the results of FIGS. 4 and 5, the dimensions of the ZnO nano particles formed on the electrode surface were increased according to the increased flow rate of O₂.

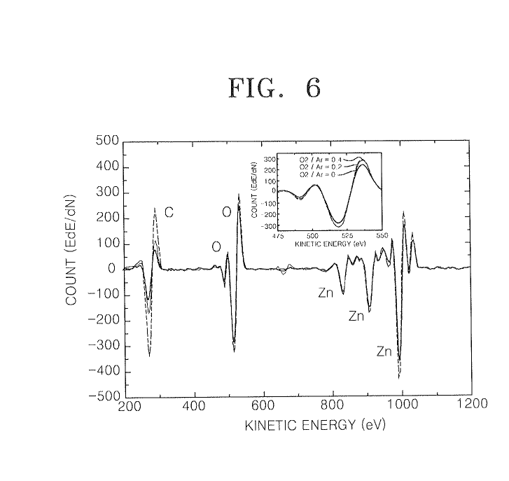

FIG. 6 illustrates an AES (Auger electron Spectroscopy) pattern with respect to the results of FIG. 4.

In FIG. 6, when the flow rate ratio of O₂/Ar was 0, 0.2 and 0.4, respectively, oxygen atoms percentage within ZnO obtained under respective states were 51.26%, 53.21%, and 54.17%. Also, Zn atoms percentage was 48.74%, 46.79%, and 45.83%, respectively. In other words, as the flow rate ratio of O₂/Ar was increased, the percentage of the oxygen atoms within ZnO was increased, so that oxygen-rich ZnO is obtained.

### EXAMPLE 3

In order to observe the change of the nano structure form associated with a growth within the reaction chamber when making the metal oxide nano structure layer grow by the method according to Example 1, two growth cases for 15 minutes and 50 minutes of the ZnO nano structure were compared under the state where the flow rate ratio (O₂/Ar) of O₂ and Ar maintains 0.2 within the reaction chamber.

For this operation, samples having electrodes by sequentially forming Ti and Cu thin films on a p-type (100) silicon substrate were prepared by the method according to Example 2. Then, the samples were classified into two groups, and ZnO is grown for 15 minutes and 50 minutes on the electrodes with respect to the two groups in a sputtering reaction chamber wherein the temperature and the pressure were maintained in the ambient environment as described in Example 1.

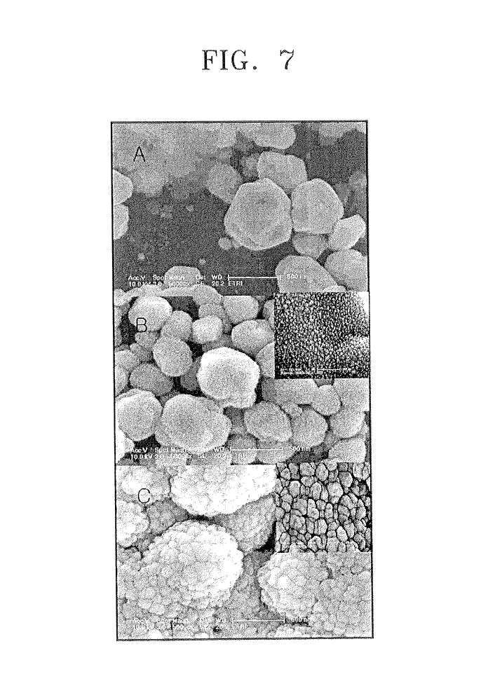

FIG. 7 shows SEM images each displaying resultant structures where the ZnO nano structures are grown as the result of Example 3.

In FIG. 7, an image A displays a surface of the Cu thin film prior to growing ZnO on the surface of the electrode, an image B corresponds to a case that ZnO was grown on the surface of the electrode for 15 minutes, and an image C corresponds to a case that ZnO was grown on the surface of the electrode for 50 minutes.

Referring to FIG. 7, a ZnO nano structure having a diameter of about 70˜100 nm was formed on the surface of the Cu/Ti electrode in case of the images B and C. Also, when the growth time of ZnO became long (in case of the image C of FIG. 7), a particle size of ZnO was further increased.

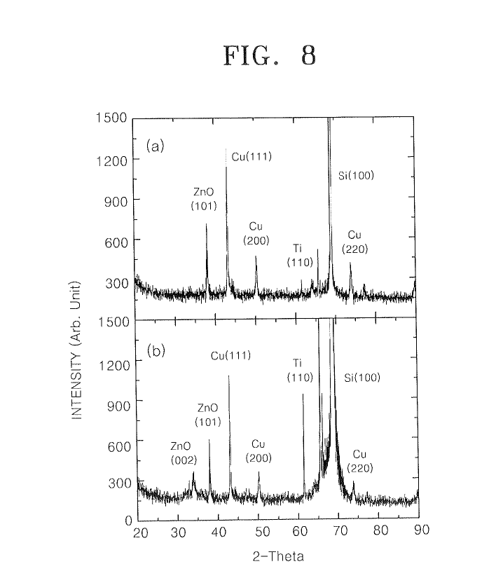

FIG. 8 illustrates results of analyzing X-ray diffraction peaks with respect to the images B and C of FIG. 7.

In FIG. 8, a graph (a) corresponds to the case of growing ZnO for 15 minutes by setting the flow rate ratio of O₂/Ar to 0.2 (corresponding to the image B of FIG. 7), and a graph (b) corresponds to the case of growing ZnO for 50 minutes by setting the flow rate ratio of O₂/Ar to 0.2 (corresponding to the image C of FIG. 7).

When comparing the graphs (b) of FIG. 8 and (c) of FIG. 5, the diffraction patterns having peaks different from the peaks of ZnO of the plane orientations (002) and (101) are identical to each other. Also, when comparing the graphs (a) and (b) of FIG. 8, the peak intensity of ZnO in the plane orientation (101) is approximately constant regardless of the increase of the growth time of ZnO, and a growth orientation of a crystalline property of ZnO clusters proceeds toward the plane orientation (002) while a growth time is increased.

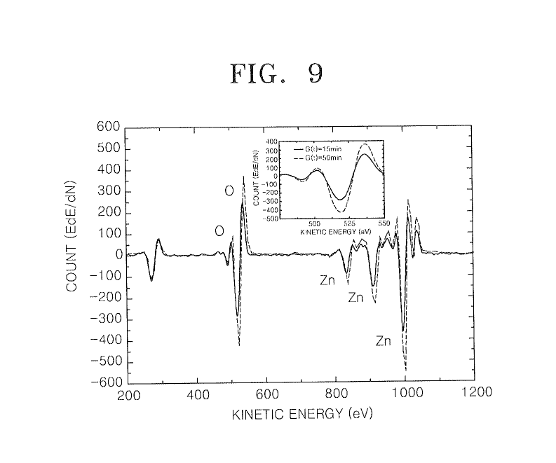

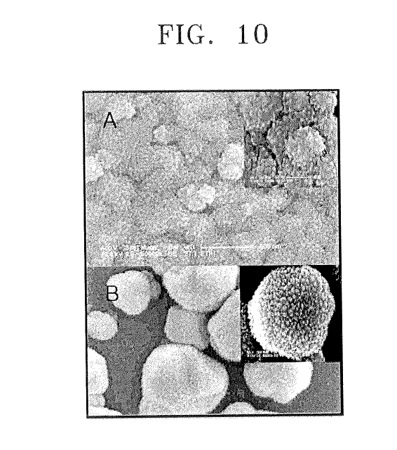

FIG. 9 illustrates an AES pattern with respect to the ZnO nano structure of the images B and C of FIG. 7.

In FIG. 9, oxygen atoms percentage within ZnO obtained when the growth time of ZnO is 15 minutes was 51.26%, and Zn atoms percentage was 48.74%. Also, when the growth time of ZnO was 50 minutes, the oxygen atoms percentage within ZnO was 53.20% and the Zn atoms percentage was 46.80%. That is, as the growth time was increased, the oxygen atoms percentage (%) within ZnO was increased so that oxygen-rich ZnO was obtained.

### EXAMPLE 4

In order to observe the change of the nano structure form according to the kind of a metal material to induce the ZnO nano structure growth within the reaction chamber when making the metal oxide nano structure layer grow by the method according to Example 1, silicon substrate samples each having different two kinds of electrodes were prepared, and the ZnO nano structure was grown for 30 minutes when the flow rate ratio (O₂/Ar) of O₂ and Ar was 0.4 within the reaction chamber with respect to the silicon substrate samples.

FIG. 10 shows SEM images each displaying results of making ZnO grow on different kinds of two electrodes.

In FIG. 10, an image A displays a case that ZnO was grown on a surface of the electrode sequentially stacked with Ti and Cu thereon, and an image B displays a case that ZnO was grown on a surface of the electrode sequentially stacked with Au and Ti thereon.

Referring to FIG. 10, the ZnO nano structures grown by the applied electrode materials had particle sizes and forms different from each other.

An integrated circuit according to the present invention has a sensor that can be formed at low temperature to prevent degradation or characteristic deterioration of other elements formed on a substrate when integrating various kinds of sensors for detecting gases and biochemical materials on a substrate having MOSFET-based elements. The integrated circuit according to the present invention provides a sensor structure for detecting gases and biochemical materials by integrating a heater, a passivation film, and a sensor, which are sequentially stacked, in an area where a heat emission window is formed in a backside of the substrate.

According to the present invention, fine unit elements having diverse composite functions can be integrated on a single substrate. Moreover, since the sensor for detecting gases and biochemical materials can be formed without a high temperature treatment, characteristic degradation caused by heating the unit elements of the integrated circuit during the thermal treatment can be prevented. By employing a metal oxide nano structure as a detection material in the sensor for detecting gases and biochemical materials, the sensor can be driven at lower power than that of the ceramic type or thick film type sensor as well as requires less power dissipation and allows for mass production by a relatively simple manufacturing process. Particularly, the characteristics of other unit elements formed on the substrate, i.e., CMOS-based circuits, fabricated for heater driving and information processing are not lowered when forming the sensor. Therefore, the present invention is useful for a sensor network system for detecting gases and biochemical materials that can drive and control a sensor using a wireless integrated circuit at a remote location by installing the integrated circuit having the sensor according to the present invention in telemetics for cars or a home network system.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An integrated circuit comprising:
a semiconductor substrate;
a sensor for detecting gases and biochemical materials, the sensor including a pair of electrodes formed on a first region of the semiconductor substrate, and a metal oxide nano structure layer formed on surfaces of the pair electrodes;
a heater formed on a second region adjacent to the sensor on the semiconductor substrate; and
a signal processor formed by a metal oxide semiconductor field effect transistor (MOSFET) formed in a third region of the semiconductor substrate to process a predetermined signal obtained from a quantity change of a current flowing through the pair of electrodes of the sensor.

2. The integrated circuit of claim 1, wherein the metal oxide nano structure layer is composed of zinc oxide, indium oxide, tin oxide, tungsten oxide, or vanadium oxide.

3. The integrated circuit of claim 1, wherein the pair of electrodes are formed of polycrystalline metal composed of Au, Cu, Ti, Ni, or a combination of these materials.

4. The integrated circuit of claim 1, wherein the pair of electrodes are formed by a stacked structure of Ni and Au, a stacked structure of Au and Cu, or a stacked structure of Ti and Cu.

5. The integrated circuit of claim 1, wherein the heater comprises an n-channel or a p-channel MOSFET.

6. The integrated circuit of claim 1, wherein the heater is formed by a stripe-shaped metal pattern with a high melting point.

7. A method of manufacturing an integrated circuit, comprising:
forming a plurality of MOSFET devices on a substrate; and
forming a sensor for detecting gases and biochemical materials on the plurality of MOSFET devices,
wherein the forming of the sensor comprises:
forming a passivation film covering the plurality of MOSFET devices on the substrate;
forming at least one pair of electrodes on the passivation film; and
forming a metal oxide nano structure layer on the surfaces of the pair of electrodes at a temperature in a range from room temperature to 400° C.

8. The method of claim 7, wherein the forming of the plurality of MOSFET devices on the substrate comprises forming a MOSFET device that constitutes a signal processor for processing a predetermined signal obtained by a quantity change of a current flowing through the pair of electrodes of the sensor.

9. The method of claim 7, wherein the forming of the plurality of MOSFET devices comprises forming a MOSFET device that constitutes a heater for supplying heat to the sensor.

10. A method of forming a sensor for detecting gases and biochemical materials, comprising:
forming electrodes on a substrate; and
forming a metal oxide nano structure layer on surfaces of the electrodes at a temperature in the range from room temperature to 400° C.

11. The method of claim 10, wherein the metal oxide nano structure layer is formed by radio-frequency (RF) sputtering.

12. The method of claim 10, wherein the metal oxide nano structure layer is composed of zinc oxide, indium oxide, tin oxide, tungsten oxide, or vanadium oxide.

13. The method of claim 12, wherein, when forming the metal oxide nano structure layer, the metal oxide nano structure layer is formed by doping a p-type impurity.

14. The method of claim 12, wherein, when forming the metal oxide nano structure layer, the metal oxide nano structure layer is formed by doping an n-type impurity.

15. The method of claim 10, wherein the forming of the metal oxide nano structure layer is performed in a chamber having a ZnO target, and by supplying ambient gas including O₂ and Ar into the chamber.

16. The method of claim 15, wherein the ambient gas comprises O₂ and Ar supplied at a flow rate ratio (O₂/Ar) of 0.2 to 0.4.

17. The method of claim 10, wherein the electrodes are composed of a polycrystalline conductive material.
